(19) United States
(12) Patent Application Publication
(10) Pub. No.: US 2010/0151599 A1
(43) Pub. Date: Jun. 17, 2010

(54) Apparatus and method for manufacturing semiconductor device

(76) Inventors: Keun-Hee Bai, Suwon-si (KR); Yong-Jin Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/654,184

(22) Filed: Dec. 14, 2009

(30) Foreign Application Priority Data
Dec. 16, 2008 (KR) 10-2008-0128063

(51) Int. Cl. H01L 21/66

(52) U.S. Cl. 438/17; 118/712; 257/E21.53

(57) ABSTRACT

A method of manufacturing a semiconductor device includes depositing material on a wafer in a process chamber to form a thin film on the wafer, a by-product layer being simultaneously formed on an inner part of the process chamber, monitoring a change in thickness or mass of the by-product layer on the inner part of the process chamber during a process in the process chamber by using a QCM installed in the process chamber, and determining an end point of the process in the process chamber based on the monitored change in thickness or mass of the by-product layer in the process chamber.

### BACKGROUND

1. Field

Example embodiments relate to an apparatus and a method of manufacturing a semiconductor device. More particularly, example embodiments relate to an apparatus and a method of determining an end point of a process in a process chamber based on a change in thickness of a material layer in the process chamber during manufacturing of the semiconductor device.

2. Description of Related Art

Generally, manufacturing of a semiconductor device may include several processing steps, e.g., forming or patterning a thin film on a wafer. Further, when the thin film is formed on a wafer in a process chamber, a product layer, i.e., a by-product layer, may be formed on an inner wall of the process chamber. During subsequent thin film processing in the process chamber, the product layer may be delaminated from the inner wall of the process chamber and, thus, may contaminate the wafer or thin film thereon. Accordingly, the inside of the process chamber may require regular cleaning to remove the product layer from the inner wall of the process chamber.

Conventional processing in the process chamber, e.g., depositing, etching, and/or cleaning, may be performed for a predetermined length of time. For example, repeated tests may be performed to set appropriate predetermined times, e.g., optimal times, for the processes to fit varying processing conditions of each process chamber. However, conventional time setting of end points, i.e., length of the processes, may be time consuming and inaccurate.

### SUMMARY

Embodiments are therefore directed to an apparatus and a method of manufacturing a semiconductor device, which substantially overcome one or more of the problems due to the limitations and disadvantages of the related art.

It is therefore a feature of an embodiment to provide an apparatus for manufacturing a semiconductor device capable of determining an end point of an etching process or a cleaning process in which only radicals remain without emission of plasma.

It is another feature of an embodiment to provide an apparatus for manufacturing a semiconductor device capable of preventing over-etching, thereby minimizing damage to a wafer or an inner part of a chamber due to excessive etching or cleaning.

It is yet another feature of an embodiment to provide an apparatus for manufacturing a semiconductor device capable of preventing an increase in processing time and costs due to excessive deposition in a vapor deposition process.

It is still another feature of an embodiment to provide an apparatus for manufacturing a semiconductor device and capable of detecting an exact degree of deposition, etching or cleaning, and a corresponding end point

It is yet another feature of an embodiment to provide a method of manufacturing a semiconductor device using the apparatus with one or more of the above features.

At least one of the above and other features and advantages may be realized by providing a method of manufacturing a semiconductor device, including depositing material on a wafer in a process chamber to form a thin film on the wafer, a by-product layer being simultaneously formed on an inner part of the process chamber, monitoring a change in thickness or mass of the by-product layer on the inner part of the process chamber during a predetermined process in the process chamber by using a quartz crystal microbalance (QCM) installed in the process chamber, and determining an end point of the predetermined process in the process chamber based on the monitored change in thickness or mass of the by-product layer in the process chamber. Further, the method may include cleaning an inside of a process chamber to remove a product layer attached to an inner part of the process chamber as a by-product in the thin film deposition process.

The depositing of the thin film may be performed by plasma enhanced chemical vapor deposition.

The removing of the product layer may be performed by remote plasma cleaning, which includes generating a plasma source in a plasma generator, extracting radicals necessary for cleaning, and injecting the radicals into the process chamber.

The monitoring may include applying a voltage to the quartz, vibrating the quartz with the natural frequency using the piezoelectric phenomenon, and changing the natural frequency of quartz depending on the thickness or mass of the product layer.

The quartz may be formed in the form of a plate to allow the product layer attached to the inner part of the process chamber in the thin film deposition process to be attached to a surface of the quartz plate.

The changing of the natural frequency of the quartz may include changing a waveform of conductance, moving a peak point of the conductance to the right (Δf), and increasing the size of the waveform (A/Ao) when the thickness of the product layer decreases.

The monitoring may include converting vibration of the quartz plate into an electrical signal by an oscillator, and expressing the electrical signal as frequency by a counter.

The determining of the end point of removing the product layer may include detecting an inflection point at which shift change of the frequency is no longer sensed, and stopping the cleaning. Monitoring the change in thickness or mass of the by-product layer may be performed continuously during cleaning of the process chamber until the end point of the cleaning is determined.

At least one of the above and other features and advantages may also be realized by providing a method of manufacturing a semiconductor device, including installing a wafer at one side of an inner part of a process chamber and quartz at another side thereof; forming a thin film on an upper surface of the wafer by physical or chemical vapor deposition, and simultaneously forming a material layer on one surface of the quartz plate at a rate equal or proportional to that of depositing the thin film during the formation of the thin film on the wafer; and applying a voltage to the quartz plate to monitor a change in thickness of the material layer, and determining an end point of depositing the thin film by monitoring the thickness of the material layer.

The monitoring may include measuring a thickness (d) of the thin film by detecting shift variation (Δf) of frequency of the quartz.

The shift variation of frequency (Δf) may decrease and the size of the waveform of conductance (A/Ao) may also decrease as the thickness of the thin film may increase.

The determining of the deposition end point based on the monitored result may include recoding the shift variation (Δf) of frequency according to a degree of deposition, and detecting an inflection point at which the variation is no longer sensed in the relationship between the shift variation of frequency (Δf) and deposition time to determine the deposition end point.

At least one of the above and other features and advantages may also be realized by providing an apparatus for manufacturing a semiconductor device, including a process chamber in which a reaction product having the same properties as a thin film is attached in the form of a material layer to an inner part of the process chamber during deposition of the thin film on a wafer; a plasma source generator configured to generate a plasma source, extract only radicals therefrom, and provide the radicals into the process chamber in order to remove the material layer; and a QCM installed at one side of the inner part of the process chamber, and configured to sense the thickness or mass of the material layer to determine an end point of removing the material layer.

The QCM may include an electroceramic material configured to convert mechanical vibration into an electrical signal using the Piezoelectric effect or convert an electrical signal into a mechanical signal, and electrodes installed at both sides of the material to apply a voltage to the material.

The electroceramic material may be composed of quartz, which reacts most sensitively to a change in thickness or mass, and formed in the form of a quartz plate to maximize the Piezoelectric effect.

The QCM may further include an oscillator configured to convert and output mechanical vibration of the quartz plate into an electrical signal, and a counter configured to receive the electrical signal output from the oscillator to measure frequency of the quartz plate.

### BRIEF DESCRIPTION OF THE DRAWINGS

Example embodiments are described in further detail below with reference to the accompanying drawings. It should be understood that various aspects of the drawings may have been exaggerated for clarity.

FIG. 1 illustrates a cross-sectional view of an apparatus with a QCM according to an example embodiment;

FIG. 2 illustrates an enlarged cross-sectional view of a QCM according to example embodiments;

FIG. 3 illustrates a graph of changing the natural frequency of a quartz plate depending on whether a material layer is loaded or unloaded;

FIG. 4 illustrates a graph of a relationship between a shift change (Of) of frequency and cleaning time according to a degree of cleaning;

FIG. 5 illustrates a flowchart of a process of determining an end point in a cleaning process; and

FIG. 6 illustrates a flowchart of a process of determining an end point in a deposition process.

### DETAILED DESCRIPTION

Korean Patent Application No. 10-2008-0128063, filed on Dec. 16, 2008, in the Korean Intellectual Property Office, and entitled: “Apparatus and Method for Manufacturing Semiconductor Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

In the drawing figures, the dimensions of layers and regions may be exaggerated for clarity of illustration. It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” “on” versus “directly on,” etc.). Like reference numerals refer to like elements throughout.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

An apparatus for manufacturing a semiconductor device and a method using the same according to example embodiments may include using a QCM to determine thickness of a material layer in a process chamber and a corresponding end point of a process forming the material layer, e.g., deposition or etching end point in a deposition or etching process. Example embodiments will be described in more detail below with reference to the accompanying figures.

A semiconductor device may be manufactured by depositing a thin film on an upper surface of a wafer, followed by further processing, e.g., patterning or etching the thin film. For example, unnecessary portions of the thin film may be removed using a mask to form a circuit pattern. The thin film may be deposited on the upper surface of the wafer by, e.g., a chemical vapor deposition (CVD) or physical vapor deposition (PVD). For example, the thin film may be formed by a plasma CVD process. After several deposition cycles, a cleaning process may be performed on the CVD or PVD apparatus.

That is, during deposition of material on a wafer in a process chamber to form the thin film, the material may also be simultaneously deposited on an inner part of the process chamber, i.e., surfaces other than the wafer, to form a product layer, i.e., a by-product layer. The product layer may have the same properties as the thin film, e.g., substantially same thickness. Thus, in order to avoid contamination by the product layer of subsequent deposition processes, e.g., particles may be generated on a surface of a subsequently formed thin film due to the product layer, a cleaning process may be necessary to regularly clean the inner part of the process chamber.

For example, the process chamber may be cleaned by a direct plasma cleaning (DPC) method, where a plasma source is placed directly inside the process chamber, e.g., after a CVD process, to facilitate direct reaction of the plasma with process gas in the process chamber. While the DPC method may provide high cleaning efficiency and productivity, e.g., using a monochromator to determine end points by sensing a wavelength emitted during a reaction of the product layer and the plasma emission inside the process chamber, the DPC method may exhibit several disadvantages. First, since plasma is generated inside the process chamber, ions present in the plasma may easily collide with the inner part of the process chamber, thereby causing direct damage to the inner part of the chamber. Second, due to a relatively long required cleaning time, the inner part of the process chamber may be over-etched, and maintenance costs for the process chamber may increase. Third, depending on the length of the cleaning time, the productivity may decrease.

In another example, the process chamber may be cleaned by a remote plasma cleaning (RPC) method, where a plasma source is placed outside the process chamber, so only radicals necessary for cleaning may be extracted therefrom to be injected into the process chamber for cleaning. It is noted that since the RPC method does not provide plasma emission inside the process chamber, use of a monochromator for sensing a reaction of the product layer and the plasma emission inside the process chamber to determine end points is not applicable thereto.

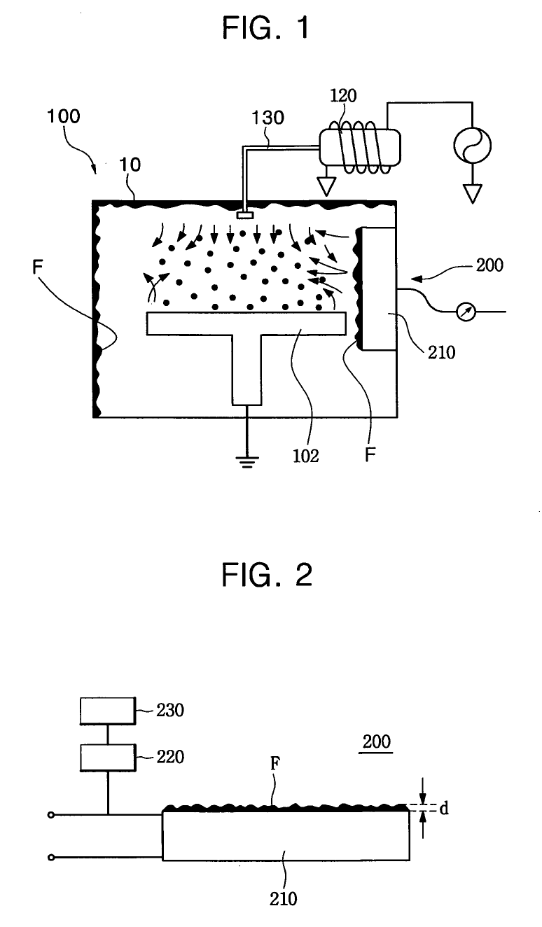

A RPC apparatus according to example embodiments for producing a plasma source outside a process chamber, and then injecting the plasma source into the process chamber will be described hereinafter with reference to FIGS. 1-2. FIG. 1 illustrates a schematic cross-sectional view of a RPC apparatus according to example embodiments. FIG. 2 illustrates an enlarged schematic cross-sectional view of a QCM according to an example embodiment.

According to example embodiments, a RPC apparatus capable of determining appropriate end points for deposition and/or removal of a by-product layer on an inner part of a process chamber may be provided. It is noted that, hereinafter, while a “thin film” on a wafer is different from “product layers” attached to an inner part of a process chamber or various devices in the process chamber, both “thin film” and “product layer” are “material layers” and have the same properties as each other. Accordingly, hereinafter, material layers are used to define all kinds of films originally formed at or derived from an inner part or one side of a device, including thin films, product layers, and powder.

As illustrated in FIG. 1, a RPC apparatus 100 may include a process chamber 110 with a fixing chuck 102 clamping a wafer, a plasma source generator 120 providing a plasma source into the process chamber 110, and a quartz crystal microbalance (QCM) 200. The plasma source generator 120 may be positioned outside the process chamber 110, and may be connected to the process chamber 110 via a source supply line 130. Accordingly, plasma may be generated in the plasma source generator 120 outside the process chamber 110, and may be injected, e.g., radicals thereof, into the process chamber 110 through the source supply line 130 to clean the inside of the process chamber 110, e.g., after a CVD process is completed.

The fixing chuck 102 may be a mechanical chuck for fixing a wafer inside the process chamber 110, e.g., a chuck physically fixing a wafer via a clamp, a vacuum chuck fixing a wafer using pressure between wafers, or an electrostatic chuck fixing a wafer using static electricity. For example, voltage used to operate the QCM 200, as will be described in more detail below, may be also used to operate the electrostatic chuck for fixing the wafer via a voltage difference between electrodes installed in the fixing chuck 102. The fixing chuck 102 may be positioned to face an input source, e.g., input of deposition or etching gas, of the process chamber 110. For example, the fixing chuck 102 may face the supply line 130.

The QCM 200 may be installed inside the process chamber 110. For example, the QCM 200 may be positioned at any part in the process chamber 110 receiving substantially same exposure to reaction gas, e.g., etching gas or deposition gas, as a wafer on the fixing chuck 102, while not interfering with the wafer processing, e.g., the QCM 200 may not overlap the supply line 130. For example, the QCM 200 may be on a part of a sidewall, ceiling, or bottom of the process chamber 110. For example, as illustrated in FIG. 1, the QCM 200 may extend along a sidewall of the process chamber 110 spaced apart from the fixing chuck 102. In another example, the QCM 200 may be installed on the fixing chuck 102, as will be described in more detail below.

The QCM 200 may include a piezoelectric material. In particular, certain materials may be distorted, e.g., deformed in shape, in an electric field, or may generate piezoelectricity in response to applied pressure. In other words, such materials, e.g., crystals, may convert mechanical vibration into an electric signal or vice versa, i.e., exhibit “piezoelectric effects.” Such materials, i.e., elements generating piezoelectric effects, may include electroceramic materials, e.g., quartz, Rochelle salt, and the like. For example, quartz may be used as a material exhibiting piezoelectric effects at frequency with high precision. Thus, the QCM 200 may include quartz, i.e., a piezoelectric material, which reacts most sensitively to a change in thickness or mass.

The QCM 200 may be formed in any suitable shape along an internal surface of the process chamber 110. For example, as illustrated in FIG. 2, the QCM 200 may be formed as a plate 210 to maximize the piezoelectric effect. That is, the QCM 200 may have a flat plate shape, so its longitudinal surface, i.e., a longer surface, may be on, e.g., directly on, an inner surface of the process chamber 110, as illustrated in FIG. 1. Electrodes may be formed by coating metals on opposite surfaces, e.g., two opposite longitudinal surfaces, of the plate 210, and an alternating voltage may be applied to the electrodes to vibrate the plate 210 at its natural frequency.

For example, when voltage is applied to both ends of the plate 210, i.e., to the electrodes, the plate 210 may mechanically vibrate. The mechanical vibration frequency of the plate 210 may be determined in accordance with a frequency constant of the material of the plate 210, e.g., a natural frequency of quartz. In other words, when the plate 210 is formed of quartz, the frequency constant of quartz may set a predetermined frequency with respect to thickness or mass of the plate 210. Therefore, any change in thickness or mass of the plate 210 may be detected by measuring the frequency.

For example, when a voltage is applied to a clean quartz plate 210 of a predetermined size and mass, the plate 210 may vibrate with the natural frequency of quartz. However, when thickness of the plate 210 changes, e.g., a product layer F is formed on the plate 210, or mass of the plate 210 changes, e.g., powder is attached to the plate 210, the frequency of the plate 210 deviates from the natural frequency of quartz and changes according to the thickness of the product layer F or the mass of the powder. Accordingly, the thickness of the product layer F or the mass of the powder attached to the plate 210 may be determined as a measured frequency change relative to a natural frequency of the plate 210, e.g., relative to the natural frequency of quartz.

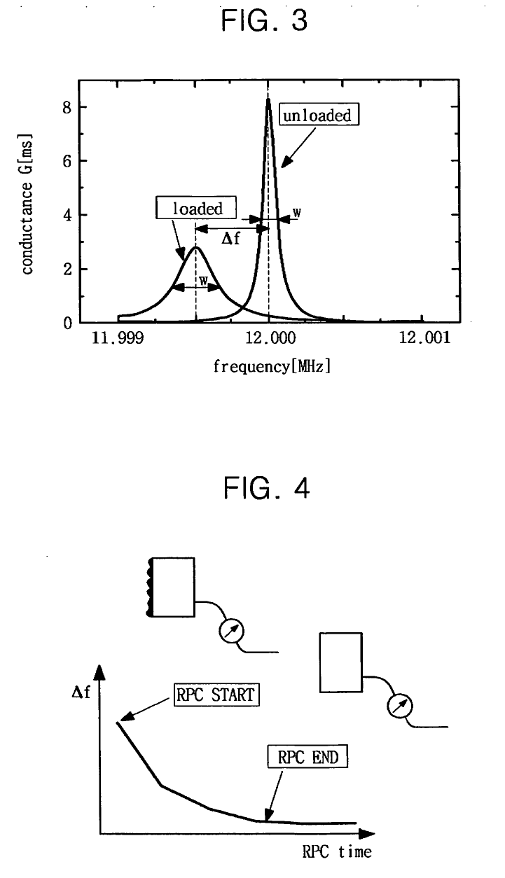

FIG. 3 illustrates a graph showing a change in the natural frequency of the plate 210 with respect to presence/absence of the product layer F thereon. It is noted that when the product layer F is removed from the plate 210, i.e., unloaded, a distribution of transforming modes is changed. That is, as a thickness of the product layer F is reduced, a peak point moves to the right along the x-axis, i.e., shift variation (Δf) changes, and a size of the waveform along the y-axis (A/Ao) increases. Thus, as the thickness of the product layer F is reduced, the change in waveform of conductance is linearly varied.

More specifically, as illustrated in FIG. 3, when the product layer F or powder having a mass is present on the surface of the quartz plate 210, as compared to absence thereof, the frequency of the plate 210 is lower than a natural frequency of the quartz. As described above, as the thickness of the product layer F is reduced, the size of the waveform (A/Ao) increases and the frequency increases. As a result, as the thickness (d) of the product layer F or a mass (m) of the powder is reduced, the frequency of the plate 210 increases to approach the natural frequency of the quartz. The thickness (d) of the product layer F or a mass (m) of the powder may be precisely measured, e.g., at any moment in time, by monitoring the shift variation (Δf) of the frequency, i.e., a difference between the natural frequency of quartz and the loaded plate 210.

The vibration of the plate 210 may be converted into an electrical signal by an oscillator 220, and the electrical signal may be expressed as frequency by a counter 230. That is, the oscillator 220 may convert and output the mechanical vibration of the quartz plate 210 into an electrical signal. The counter 230 may receive the electrical signal output from the oscillator 220 and may measure the frequency of the quartz plate 210.

FIG. 4 illustrates shift variation (Δf) of frequency according to a degree of cleaning. It is noted that the degree of cleaning is reflected in FIG. 4 as a length of cleaning time along the x-axis.

As described previously, the thickness (d) of the product layer F or the mass (m) of powder may be measured by detecting the frequency change using the QCM 200 in the process chamber 110. Further, a point at which the product layer F or the powder are completely removed from the QCM 200, i.e., a point at which the thickness (d) and/or the mass (m) substantially equal zero, may be determined as a cleaning end point, i.e., cleaning of the process chamber 110 may be stopped.

As illustrated in FIG. 4, the cleaning end point may be determined by detecting an inflection point at which the shift variation (Δf) is no longer detected in the relationship between the shift variation (Δf) of frequency and cleaning time, e.g., deposition time or etching time. In other words, as illustrated in FIG. 4, cleaning of the process chamber 110 may start when the product layer F on the quartz plate 210 has a thickness (d). As the cleaning time progresses, i.e., RPC time along the x-axis in FIG. 4, the shift variation (Δf) decreases. At the cleaning end point, i.e., RPC end in FIG. 4, the entire product layer F is substantially removed and the shift variation (Δf) stops changing. Thus, detection of a point in time that the shift variation (Δf) stops changing, e.g., equals zero, indicates the cleaning end point in the process chamber 110.

The RPC apparatus 100 according to example embodiments may generate plasma outside the process chamber 110, so damage to the inner part of the process chamber 110, e.g., as compared to the DPC method, may be prevented or substantially minimized. Further, remote plasma generation by the RPC apparatus 100 may reduce cleaning time and over-etching of the inner part of the process chamber 110, e.g., as compared to the DPC method.

In addition, the RPC apparatus 100 according to example embodiments may have a substantially improved estimation of a degree of cleanliness inside the process chamber 110 via the QCM 200, e.g., as compared to conventional apparatuses, thereby providing real-time cleaning times, i.e., avoiding using predetermined cleaning times based on time set through previously repeated tests. Therefore, even if several processing conditions in the RPC apparatus 100 change, e.g., deterioration of the process chamber, the cleaning time, i.e., end point, according to example embodiments may be adjusted in real time based on the QCM 200 monitoring without relying on predetermined cleaning times, e.g., a new processing condition may not require long-term tests for determining a new predetermined cleaning time. Further, according to example embodiment, a cleaning end point may be determined in each sub-step.

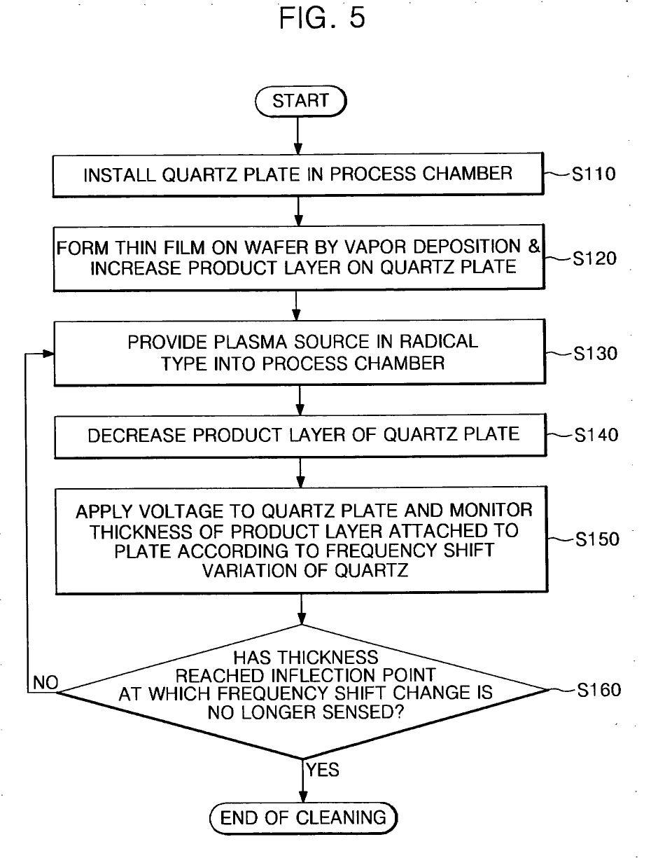

According to one example embodiment, a method of determining an end point in a cleaning process will be described in more detail below with reference to FIG. 5. FIG. 5 illustrates a flowchart of a process of determining the cleaning process end point.

As illustrated in FIG. 5, the QCM 200 may be installed in the process chamber 110, i.e., operation S110. Next, a wafer may be processed in the process chamber 110, e.g., a thin film may be formed on the wafer by vapor deposition in operation 5120. Simultaneously, the product layer F may be formed on a surface of the quartz plate 210, i.e., in operation S120. A cleaning process may be performed in the chamber process 100 in operation S130, e.g., radicals of a plasma source may be provided into the process chamber. Accordingly, a thickness of the product layer F attached to the quartz plate 210 may be gradually reduced, i.e., operation 5140. A voltage may be applied to the quartz plate 210, i.e., operation S150, so the thickness of the product layer F on the quartz plate 210 may be monitored according to the shift variation (Δf) of quartz in the quartz plate 210. In operation S160, it may be determined whether the shift variation (Δf) has reached the inflection point, i.e., a point at which the shift variation (Δf) stops changing. It is noted that operations S140 through S160 may be performed during performance of operation S130. Once it is determined that the shift variation (Δf) has reached the inflection point, the cleaning process in operation S130, e.g., provision of the plasma source, may be stopped, resulting in an end of the cleaning.

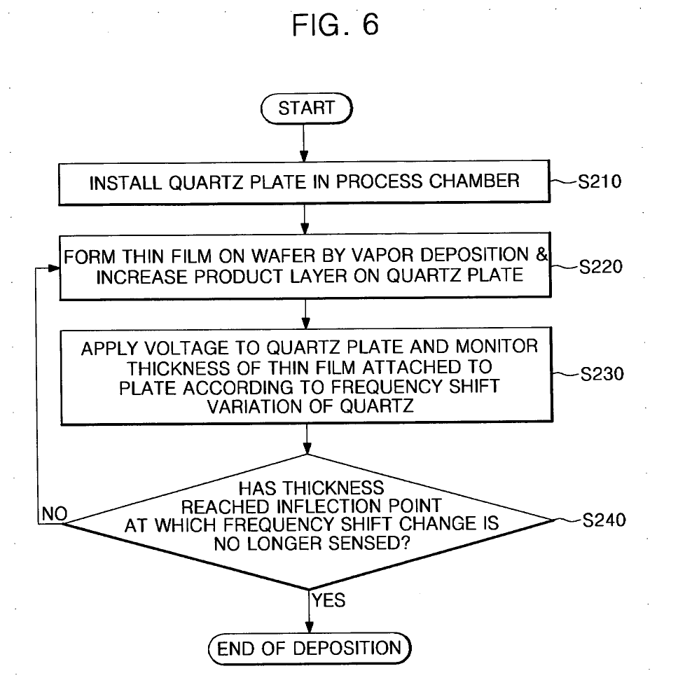

According to another example embodiment illustrated in FIG. 6, the QCM 200 may be installed at one side of the process chamber 110, i.e., operation S210, so appropriate processing time, e.g., thin film deposition time, may be determined. For example, when physical or chemical vapor deposition is performed on a wafer in the process chamber 110, deposition is simultaneously performed on the surface of the quartz plate 210 placed at on side of the process chamber, i.e., operation 5220. When a material is deposited on the quartz plate 210, i.e., when the product layer F is formed on the quartz plate 210, the vibration frequency of the quartz plate 210, i.e., shift variation (Δf), changes according to the thickness or mass of the product layer

F. While monitoring the shift variation of frequency (operation S230), the deposition may be continued until the shift variation (Δf) is no longer sensed (operation S240), e.g., a predetermined value of shift variation (Δf) as correlated to a desired thin film thickness may be achieve, resulting in completing optimal deposition of the thin film on the wafer to a desired thickness.

According to another example embodiment, an etching time may be determined using the QCM 200 in an etching process. In particular, a thin film may be deposited on a wafer in a thin film deposition process, and a desired pattern may be formed in the thin film using an etch mask.

More particularly, the process chamber 110 described previously with reference to FIGS. 1 and 5 may be used, e.g., a process chamber for physical or chemical vapor deposition with the external plasma source generator 130 and the QCM 200. However, the process chamber 110 may include an electrostatic fixing chuck using static electricity for fixing a wafer thereon, and a quartz plate 210 on the electrostatic chuck. Thus, the natural frequency of the quartz plate may be changed according to a change in thickness or mass of the thin film formed on the wafer fixed by the electrostatic chuck, and the thickness (d) of the thin film may be estimated by detecting shift variation (Δf) of the natural frequency. The shift variation of frequency according to a degree of etching may be recorded, thereby determining an etching end point at an inflection point at which the shift variation is no longer sensed even when an etching time has elapsed.

In contrast, a conventional etching process, as several variables are necessary for etching, may be performed only for a set time without sufficient consideration of changed process conditions. Therefore, satisfactory deposition or etching via a conventional process may not be ensured. For example, over-deposition or over-etching may occur. Further, as changed process conditions, e.g., in a conventional deposition or etching process, may require repeated testing for determining new predetermined process times, productivity may be substantially reduced, e.g., as compared to example embodiments.

According to example embodiments, an apparatus and method for manufacturing a semiconductor device may be provided to determine an end point of depositing a thin film in a thin film deposition process of depositing a thin film on a wafer, or to determine an end point of removing the thin film or a product layer in an etching process of depositing the thin film on the wafer and then removing the thin film to form a desired pattern or in a cleaning process of removing a reaction product layer that is attached to an inside of a process chamber as a by-product in the thin film deposition process and generates particles. In particular, according to example embodiments, a QCM may be installed in a process chamber to determine an end point of depositing or etching a thin film, or an end point of cleaning the process chamber, e.g., in a process of removing unwanted material from the process chamber by plasma after deposition of a thin film. Therefore, in a method of manufacturing a semiconductor device, mass or thickness of a product layer may be determined by detecting a change in the natural frequency of, e.g., quartz, so determining a cleaning end point to remove the product layer attached to the inside of the process chamber as a by-product during the thin film deposition process may be performed.

Consequently, as vibration frequency of a quartz plate changes according to thickness or mass of material deposited thereon as compared to a natural frequency of quartz, when the material deposited on the quartz plate, i.e., a product layer or a material layer of powder on the quartz plate, is removed from the quartz plate by cleaning, the frequency changes. Thus, it can be noted that example embodiments provide an apparatus for determining an end point of a thin film deposition (or etching) process or an end point of cleaning by detecting a change in mass or thickness on the quartz plate. As such, the deposition, etching, or cleaning process, according to example embodiments, may be optimized by sensing an increase or decrease in thickness or mass, i.e., via detecting the change of shifting frequency, and determining an optimal end point at an inflection point at which the frequency no longer shifts. Therefore, use of repeated tests to set predetermined times and/or over-deposition (or over-etching) may be eliminated or substantially minimized.

In contrast, a conventional RPC apparatus, e.g., using a residual gas analyzer for analyzing mass of a residual gas in a process chamber, may be expensive and may have a limited ability to detect radicals. Further, the conventional RPC apparatus may be inaccurate, e.g., exhibit fluctuations due drastic changes in the radical intensity depending on various conditions and exhibit inaccurate reflection inside the process chamber due to its position in the exhaust pipe.

As described above, example embodiments may provide the following effects. First, an appropriate etching or cleaning end point may be determined even when plasma is not necessarily generated and thus only radicals are present. Second, since an optimal end point can be determined, increases in costs and processing time due to excessive deposition can be prevented, or damage to a wafer or an inner part of a chamber due to excessive etching or cleaning can be prevented. Third, since a QCM is installed in a process chamber to determine an end point, reliability can be enhanced, and precision can also be enhanced.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

1. A method of manufacturing a semiconductor device, comprising:
depositing material on a wafer in a process chamber to form a thin film on the wafer, a by-product layer being simultaneously formed on an inner part of the process chamber;
monitoring a change in thickness or mass of the by-product layer on the inner part of the process chamber during a predetermined process in the process chamber by using a quartz crystal microbalance (QCM) installed in the process chamber; and
determining an end point of the predetermined process in the process chamber based on the monitored change in thickness or mass of the by-product layer in the process chamber.

2. The method as claimed in claim 1, wherein depositing material on the wafer in the process chamber is performed by plasma enhanced chemical vapor deposition.

3. The method as claimed in claim 1, further comprising cleaning an inside of the process chamber, after forming the thin film on the wafer, to remove the by-product layer from the inner part of the process chamber, wherein:
monitoring the change in thickness or mass of the by-product layer on the inner part of the process chamber is performed during the cleaning to monitor removal of the by-product layer from the process chamber, and
determining the end point of the predetermined process includes determining the end point of the cleaning based on the monitored change in thickness or mass of the by-product layer on the QCM.

4. The method as claimed in claim 3 wherein cleaning the process chamber to remove the by-product layer is performed by remote plasma cleaning, the remote plasma cleaning including generating a plasma source in a plasma generator, extracting radicals necessary for cleaning, and injecting the radicals into the process chamber.

5. The method as claimed in claim 3, wherein monitoring the change in thickness or mass of the by-product layer includes:
applying voltage to the QCM to trigger vibration thereof, the QCM vibrating at a natural frequency of quartz when having substantially no by-product layer thereon; and
determining a change in a vibration frequency of the QCM relative to the natural frequency of the quartz during the cleaning.

6. The method as claimed in claim 5, wherein monitoring the change in thickness or mass of the by-product layer includes forming the QCM of plate-shaped quartz, such that the by-product layer is formed along a surface of the plate-shaped quartz during material deposition.

7. The method as claimed in claim 5, wherein determining the change in the vibration frequency of the QCM includes determining a change in a waveform of conductance, and determining an increase of a peak point of the conductance and increase in a size of the waveform when the thickness of the product layer decreases.

8. The method as claimed in claim 5, wherein determining the change in the vibration frequency of the QCM includes converting the vibration frequency of the QCM into an electrical signal by an oscillator, and expressing the electrical signal as frequency by a counter.

9. The method as claimed in claim 5, wherein monitoring the change in thickness or mass of the by-product layer is performed continuously during cleaning of the process chamber until the end point of the cleaning is determined.

10. The method as claimed in claim 5, wherein determining the end point of the cleaning of the process chamber includes detecting an inflection point at which the change in the vibration frequency of the QCM relative to the natural frequency of the quartz is no longer sensed.

11. The method as claimed in claim 1, wherein:
monitoring the change in thickness or mass of the by-product layer on the inner part of the process chamber is performed during the thin film deposition to monitor deposition thickness of the thin film, and
determining the end point of the predetermined process includes determining the end point of the thin film deposition based on the monitored change in thickness or mass of the by-product layer on the QCM.

12. A method of manufacturing a semiconductor device, comprising:
installing a wafer and a quartz crystal microbalance (QCM) inside a process chamber;
forming a thin film on an upper surface of the wafer by physical or chemical vapor deposition, a by-product layer being simultaneously formed on a surface of the QCM at a rate equal or proportional to that of the wafer processing;
applying voltage to the QCM to monitor a change in thickness of the by-product layer; and
determining an end point of forming the thin film by monitoring the thickness of the by-product layer on the QCM.

13. The method as claimed in claim 12, wherein monitoring thickness of the material layer includes detecting a shift variation of frequency of quartz in the QCM.

14. The method as claimed in claim 13, wherein the shift variation of frequency and a size of the waveform of conductance decrease as the thickness of the thin film increases.

15. The method as claimed in claim 12, further comprising:
removing at least a portion of the thin film; and
determining the end point of the thin film removing based on a shift variation of frequency of quartz in the QCM.

16. (canceled)

17. (canceled)

18. (canceled)

19. (canceled)

20. (canceled)
